(19) United States
(12) Patent Application Publication
(10) Pub. No.: US 2012/0226953 A1
(43) Pub. Date: Sep. 6, 2012

(54) SEMICONDUCTOR INTEGRATED CIRCUIT, DESIGN APPARATUS AND DESIGN METHOD

(75) Inventors: Masato NAKAZATO, Kawasaki-Shi (JP); Kenichi ANZOU, Kawasaki-Shi (JP); Tetsu HASEGAWA, Yokohama-Shi (JP)

(73) Assignee: KABUSHIKI KAISHA TOSHIBA, Tokyo (JP)

(21) Appl. No.: 13/235,175

(22) Filed: Sep. 16, 2011

(30) Foreign Application Priority Data
Mar. 2, 2011 (JP) 2011-045146

(51) Int. Cl. G01R 31/3177; G06F 11/25

(52) U.S. Cl. 714/726; 714/E11.155

(57) ABSTRACT

A semiconductor integrated circuit has one or more of scan chains each having series-connected flip-flops that exist in an internal circuit. Each scan chain is divided into a plurality of segments. Each segment is controllable a timing of a clock signal. The semiconductor integrated circuit has a clock gating circuit capable of being shared by the scan chains and configured to generate a plurality of clock signals for driving each segment, the clock gating circuit being provided for each scan chain, and a segment control signal generator configured to generate a control signal to be used when the clock gating circuit generates the clock signals so that an effect of a fault of the internal circuit is transferred through one of the segments and care bits corresponding to a next fault are captured in a corresponding segment.

### CROSS REFERENCE TO RELATED APPLICATIONS

This application is based upon and claims the benefit of priority from the prior Japanese Patent Application No. 2011-45146, filed on Mar. 2, 2011, the entire contents of which are incorporated herein by reference.

### FIELD

Embodiments of the present invention relate to a semiconductor integrated circuit, a design apparatus, and a design method capable of verifying a circuit for faults using a scan chain.

### BACKGROUND

Recent power-saving type semiconductor integrated circuits are designed so that the entire system can operate at a low power using a power saving technique. Clock gating is a representative of the power saving technique. The clock gating is a technique for reducing power consumption occurring at a register and a combinational logic connected to the output of the register by halting clocks of the register in a block that is not used in the system operation. In this technique, a clock gating circuit is connected to a clock-signal line that is connected to the register, and the clock gating circuit is controlled by a control signal so that the clock gating circuit does not output the clock signal.

In general, power-saving type semiconductor integrated circuits require different ways of control of clock signals in a normal system operation and a test operation. In the system operation, a signal from a clock control circuit in a semiconductor integrated circuit is input to a clock gating circuit so that as the clock gating circuit does not output the clock signals more than necessary, thereby reducing power consumption. However, the circuits are designed so that clock signals are always output from the clock gating circuit in the test operation. Therefore, power consumption may increase in the test operation compared to the system operation.

There are a can test and a compression scan tests popular techniques for testing a semiconductor integrated circuit.

In the scan test, a semiconductor circuit is provided with external scan input and output terminals. Connected between the terminals is one or more of scan chains having series-connected flip-flops (scan registers) of the semiconductor circuit. Signals traveling through the scan chains are observed in the scan test. In detail, test data supplied from external test equipment such as a simulator, are input to the scan chains via the external scan input terminals. The test data are shifted one after another and set in each scan register in the scan chains. The test data set in the scan registers are shifted one after another in accordance with system clocks and then input to the test equipment, via the external scan output terminals.

In the compression scan test, a data dissemination circuit and a data compression circuit are provided at the external scan input and output terminals sides, respectively. Connected between the data dissemination and compression circuits are a large number of scan chains. The compression scan test has a characteristic in which it is possible to decrease the number of external input and output test terminals.

In both of the scan test and compression scan test, clock signals have to be always input to all scan registers along a scan path when data are shifted one by one from the external scan input terminals to the external scan output terminals. Therefore, each scan register and a combinational logic connected to this scan register are always put in an active state. This may cause IR drop in which a power-supply voltage abruptly drops, extreme power consumption that exceeds power limitation defined in design, thereby preventing the semiconductor integrated circuit from normal operation. As a result, there is a likelihood that a chip which normally operates in the system operation may not operate normally in the test operation, thereby causing Over-kill which determines to be defective more than necessary.

### BRIEF DESCRIPTION OF THE DRAWINGS

FIG. 1 is a circuit diagram of a semiconductor integrated circuit 1 according to the present embodiment;

FIG. 2 is a circuit diagram showing an example of the internal configuration of a clock gating circuit 3;

FIG. 3 is a circuit diagram showing an example of the internal configuration of a segment control circuit 5;

FIG. 4 is a circuit diagram showing an example of the internal configuration of a PRPG circuit 14 of FIG. 3;

FIG. 5 is a flow chart showing an example of a test-pattern generating process performed by a design apparatus 7;

FIG. 6 is a view explaining the outline of a fault detecting process of the present embodiment;

FIG. 7 is a view explaining an operation in which, while an effect D of a fault in the semiconductor integrated circuit 1 is being output from a particular segment, care bits used for making the next fault appear are captured in segments;

FIG. 8 is a view explaining an operation in which, while an effect D of a fault in the semiconductor integrated circuit 1 is being output from a particular segment, care bits used for making the next fault appear are captured in segments;

FIG. 9 is a view of an example in which the order of segments aligned in a scan chain 2 is changed;

FIG. 10 is a circuit diagram schematically showing the configuration of a semiconductor integrated circuit 1 according to a fourth embodiment; and

FIG. 11 is a circuit diagram schematically showing the configuration of a semiconductor integrated circuit 1 according to a fifth embodiment.

### DETAILED DESCRIPTION

Embodiments will now be explained with reference to the accompanying drawings.

A semiconductor integrated circuit having one or more of scan chains each having series-connected flip-flops that exist in an internal circuit. Each scan chain being divided into a plurality of segments, each segment being controllable a timing of a clock signal. The semiconductor integrated circuit has the followings.

A clock gating circuit capable of being shared by the scan chains and configured to generate a plurality of clock signals for driving each segment, the clock gating circuit being provided for each scan chain.

A segment control signal generator configured to generate a control signal to be used when the clock gating circuit generates the clock signals so that an effect of a fault of the internal circuit is transferred through one of the segments and care bits corresponding to a next fault are captured in a corresponding segment.

Based on the control signal, the clock gating circuit applies the clock signal to one of the segments so that the effect of the fault of the internal circuit is transferred through the one segment, applies the clock signal to a particular segment so that care bits for making a fault appear are captured in the particular segment, and stops the clock signal to a segment that does not have no relation with capture of the care bits and extraction of the fault.

### Basic Concept of Embodiment

The basic concept of the present embodiment will be explained first. There are a large number of flip-flops in a semiconductor integrated circuit. These flip-flops are connected in series to make a scan chain. A test pattern is then applied to the semiconductor integrated circuit to activate the circuit. Signals generated in the activated semiconductor integrated circuit are transferred through the scan chain and output from the circuit for verification. This technique for verifying a semiconductor integrated circuit is referred to as a scan test. Each flip-flop in the scan chain is referred to as a scan register.

In the case of scan test with an automatic test-pattern generator, only some scan registers in a scan chain are observed for detecting faults in a semiconductor integrated circuit. There is no need to set data in and observe all scan registers of the scan chain. That is, it is enough for the scan test to observe the data of a scan register that receives an effect D of a fault and to capture care bits required for making the next fault appear in the scan register.

However, a scan chain is a shift register composed of a plurality of series-connected scan registers. Data have to be shifted one by one from the input-side scan register to the output-side scan register. Therefore, a normal shift operation is not performed if a clock signal is applied to only some scan registers.

For that reason, in the present embodiment, a scan chain is divided into a plurality of segments and a clock signal is applied to each segment in order to switch each segment for a shift operation. That is, a test pattern is input to a semiconductor integrated circuit while a clock signal is not applied to a segment that is not related to the current scan test so that an effect D of an appearing fault can be quickly extracted to the outside, and care bits required for making the next fault appear is quickly captured in a desired segment.

### Concrete Embodiment

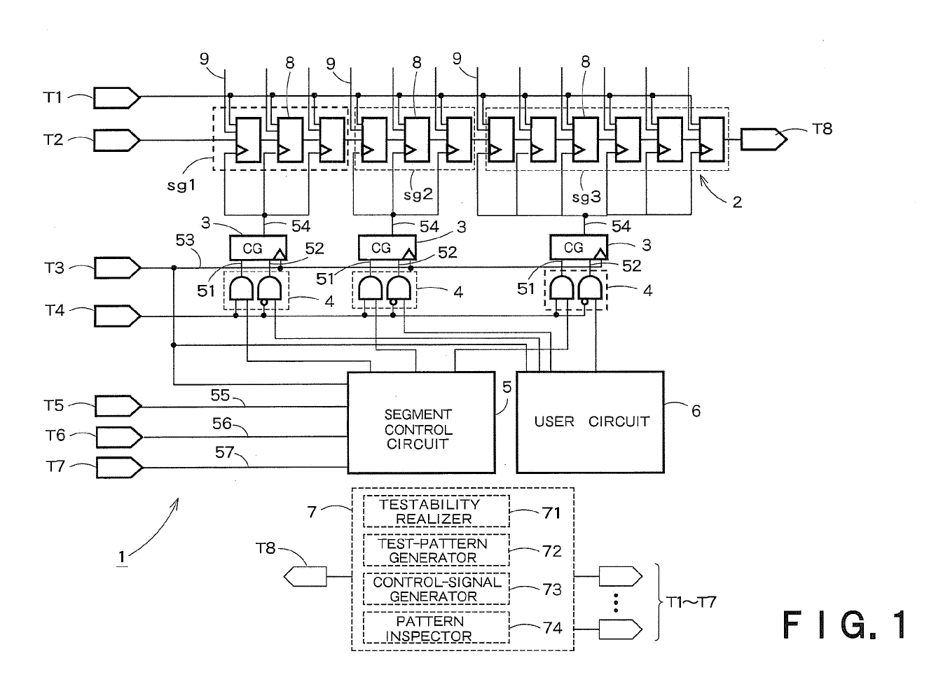

FIG. 1 is a circuit diagram of a semiconductor integrated circuit according to the present embodiment. The semiconductor integrated circuit 1 of FIG. 1 is provided with one or more of scan chains 2, a plurality of clock gating circuits 3, a plurality of control-signal selection circuits 4, a segment control circuit 5, and a user circuit 6. The input and output terminals of the semiconductor integrated circuit 1 are connected to a design apparatus 7 depicted by a broken line in FIG. 1. The design apparatus 7 may be composed of a plurality of apparatuses, but FIG. 1 shows that the design apparatus 7 is composed of a single apparatus 7.

Although FIG. 1 shows a single scan chain 2, a plurality of scan chains 2 may be provided. When a plurality of scan chains 2 are provided, a plurality of clock gating circuit 3 and a plurality of control-signal selection circuits 4 are provided for each scan chain 2. However, even if a plurality of scan chains 2 are provided, only one segment control circuit 5 is provided. In other words, the segment control circuit 5 is shared by all scan chains 2.

The scan chain 2 is composed of series-connected flip-flops (scan registers) 8 in the semiconductor integrated circuit 1, for a scan test. One or a plurality of scan chains 2 are provided in the semiconductor integrated circuit 1. Each scan chain 2 is divided into a plurality of segments each equipped with a clock gating circuit 3.

The scan chain 2 is provided with a scan enable terminal T1. By switching the logic state of a signal at the scan enable terminal T1, the scan chain 2 performs a shift operation or capture parallel input data 9. The parallel input data 9 indicate the logic state of signals at internal nodes in the semiconductor integrated circuit 1. By controlling the switching timing of the scan enable terminal T1, it is possible to capture the logic state of signals at the internal nodes at any timing and in any mode of the semiconductor integrated circuit 1 which operates in response to a test pattern applied thereto.

In addition, the semiconductor integrated circuit 1 has an external scan input terminal T2, an external clock terminal T3, an external control-signal switching terminal T4, an initialization terminal T5, a seed input terminal T6, a hold terminal T7, and a seed output terminal T8. These terminals are connected to the design apparatus 7.

Each clock gating circuit 3 controls whether a clock signal 54 is applied to each scan register 8 of the corresponding segment. Each control-signal selection circuit 4 selects either a signal generated by the segment control circuit 5 or a signal generated by the user circuit 6 in accordance with the logic state of a signal at the external control-signal switching terminal T4. The selected signal is input to the corresponding clock gating circuit 3 and made to be synchronized with an external clock signal 53, thereby generating the clock signal 54 described above.

The user circuit 6 is a circuit for implementing original functions of the semiconductor integrated circuit 1. Each control-signal selection circuit 4 receives a signal from the user circuit 6 to normally operate the semiconductor integrated circuit 1. In other words, each control-signal selection circuit 4 selects a signal generated by the segment control circuit 5 only for a scan test.

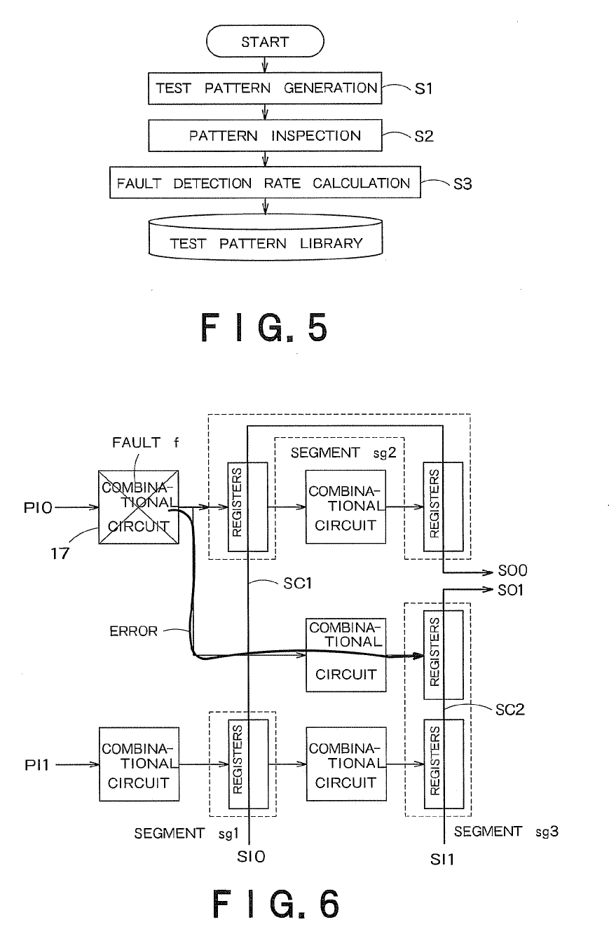

The design apparatus 7 of FIG. 1 performs the design of the semiconductor integrated circuit 1, the verification of a test pattern, and the verification of the operation of the semiconductor integrated circuit 1 using a test pattern. The operation of the design apparatus 7 will be explained later with reference to FIG. 5. As the internal configuration, the design apparatus 7 is provided with a testability realizer 71, a test-pattern generator 72, a control-signal generator 73, and a pattern inspector 74.

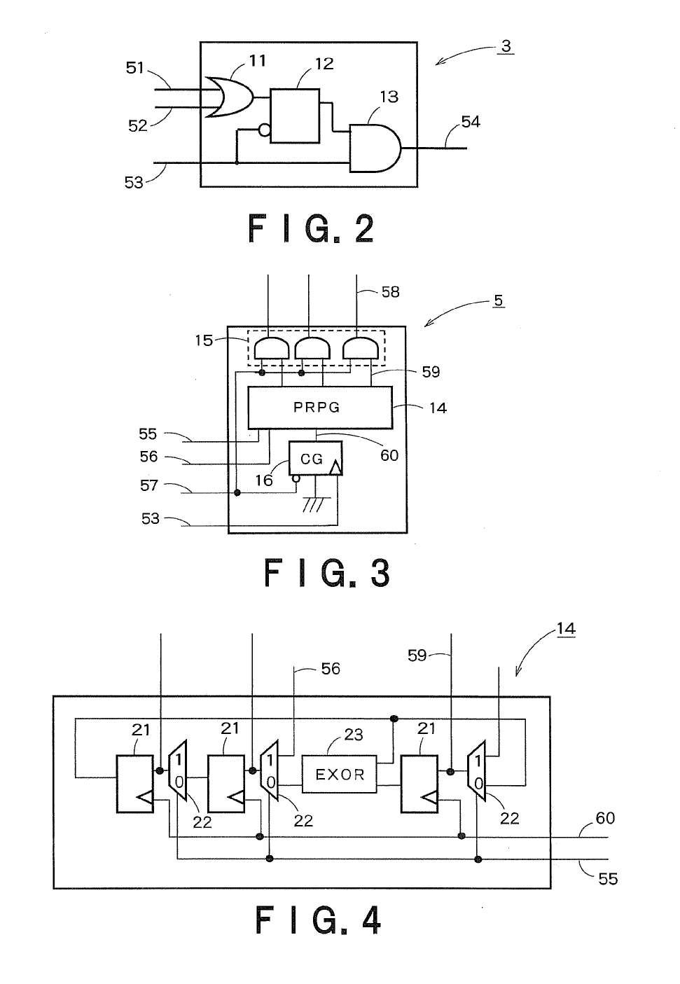

FIG. 2 is a circuit diagram showing an example of the internal configuration of each clock gating circuit 3. The clock gating circuit 3 of FIG. 2 has an OR circuit 11 for generating a signal that is a logical sum of a gating control signal generated by the segment control circuit 5 and a signal generated by the user circuit 6, a latch circuit 12 for latching the output signal of the OR circuit 11 using an external clock signal 53, and an AND circuit 13 for generating a signal that is a logical product of the output signal of the latch circuit 12 and the external clock signal 53. A low-level output of the OR circuit 11 causes the latch circuit 12 and the AND circuit 13 to output a low-level signal each so that the clock gating circuit 3 does not generate the clock signal 54. Therefore, so that the clock signal 54 is not applied to any segment, the segment control circuit 5 and the user circuit 6 both output a low-level signal to cause the OR circuit 11 of the clock gating circuit 3 corresponding to the segment to output a low-level signal. When the external clock signal 53 is stopped, the clock signal 54 is not applied to any segment.

As shown in FIG. 1, the segment control circuit 5 generates a gating control signal 52 based on an initialization signal 55, a hold signal 57, and a seed input signal 56. The initialization signal 55, the hold signal 57, and the seed input signal 56 are input via the initialization terminal T5, the hold terminal T7 and the seed input terminal T6, respectively.

FIG. 3 is a circuit diagram showing an example of the internal configuration of the segment control circuit 5. The segment control circuit 5 of FIG. 3 has a 3-bit PRPG (Pseudo Random Pattern Generation) circuit 14, a plurality of AND circuits 15 connected to the output terminals of the PRPG circuit 14, and a clock gating circuit 16 for generating a clock signal 53 to the PRPG circuit 14.

The PRPG circuit 14 performs a shift operation in synchronism with a clock signal 60 output from the clock gating circuit 16, with a seed input signal 56 as an initial value to repeatedly generate a plurality of pseudo random numbers. Input to the AND circuits 15 and the clock gating circuit 16 is a hold signal 57. For example, if the hold signal 57 is high, the clock gating circuit 16 does not output a clock signal 60. This causes the PRPG circuit 14 not to perform a shift operation but to hold the preceding pseudo random numbers. The AND circuits 15 output the pseudo random numbers held by the PRPG circuit 14 as they are. On the other hand, for example, if the hold signal 57 is low, the clock gating circuit 16 outputs a clock signal 60 in synchronism with the external clock signal 53. Therefore, the PRPG circuit 14 performs a shift operation to generate new pseudo random numbers. If the hold signal 57 is low, the AND circuits 15 do not output pseudo random numbers generated by the PRPG CIRCUIT 14, thus the segment control circuit 5 outputs a signal fixed at a low level.

FIG. 4 is a circuit diagram showing an example of the internal configuration of the PRPG circuit 14 of FIG. 3. FIG. 4 shows an example of generating 3-bit pseudo random numbers based on a 3-bit seed input signal 56. The PRPG CIRCUIT 14 of FIG.4 has three flip-flops 21 connected in a ring shape, multiplexers 22 and EXOR circuits 23 each connected between the succeeding stages of the flip-flops 21. When an initial value (the seed input signal 56) is given to a specific generator polynomial, the PRPG circuit 14 performs a shift operation in synchronism with a clock signal 60 to generate pseudo random numbers. The internal configuration of the PRPG circuit 14 is realized from a generator polynomial. The circuit configuration changes as the generator polynomial changes.

Since the generator polynomial of the PRPG circuit 14 is known beforehand, what pseudo random numbers are generated per clock cycle is predictable with the initial value. Therefore, by adjusting the initial value and the number of clock signals 60, the timing of clock signals 54 output from the clock gating circuits 3 can be freely controlled. Accordingly, clock gating can be freely performed with the PRPG circuit 14 for each segment of the scan chain 2.

Here, the clock gating controls the timing of the clock signal 54 to be input to each segment in the scan chain 2.

In the semiconductor integrated circuit 1, a plurality of scan chains 2 are provided as an example. In the present embodiment, each scan chain 2 is divided into a plurality of segments, to each of which a clock signal 54 is applied, and the timing of which is controlled by the segment control circuit 5. For simplicity, one scan chain 2 is explained hereinbelow, but the other scan chains 2 operate in the same way.

Explained next is the design apparatus 7 for designing the semiconductor integrated circuit 1 of FIG. 1. The design apparatus 7 designs the semiconductor integrated circuit 1 of FIG. 1 based on given design information and then performs the verification of the operation of the designed semiconductor integrated circuit 1. The operation verification requires a test pattern to be applied to the semiconductor integrated circuit 1 for operation simulation. Before the operation simulation, it is required to generate a test pattern and inspect the test pattern for effectiveness.

FIG. 5 is a flow chart showing an example of a test-pattern generating process performed by the design apparatus 7. This flow chart shows process steps for the design apparatus 7 having the test-pattern generator 72, the control-signal generator 73, and the pattern inspector 74, as shown in FIG. 1.

Firstly, the test-pattern generator 72 generates test pattern for the operation verification of a designed semiconductor integrated circuit 1 (step S1). The test pattern includes several types of control signals that are generated by the control-signal generator 73. The control signals are input to the semiconductor integrated circuit 1 when the operation verification is performed for the semiconductor integrated circuit 1.

Next, the pattern inspector 74 performs the pattern verification to determine whether the test pattern generated in step S1 is effective for the operation verification of the semiconductor integrated circuit 1 (step S2).

Fault simulation is then performed to calculate a fault detection rate that indicates a rate of the number of detectable faults (step S3). When the fault detection rate is low, step S1 and the succeeding steps are repeated. A test pattern having a high fault detection rate is determined as an effective test pattern and then stored in a memory (not shown).

Explained in detail below are a detection process for detecting an effect D of a fault and a setting process for capturing care bits in the scan chain 2, which are required for making the next fault appear. Both processes are required for the fault simulation in accordance with the flow chart of FIG. 5. These processes are together referred to as a fault detection process hereinbelow.

In the present embodiment, the flip-flops 8 in the semiconductor integrated circuit 1 designed by the design apparatus 7 are connected in series to make one or more of scan chains 2. Each scan chain 2 is divided into a plurality of segments. Then, clock gating is performed for each segment to switch the clock signal 54 to the segment for a shift operation. In this way, an effect D of a fault that appears using the generated test pattern is output via any of the segments.

FIG. 6 is a view explaining the outline of a fault detecting process of the present embodiment. FIG. 6 shows an example of making a scan chain sc1 from SI0 to SO0 and a scan chain sc2 from SI1 to SO1 using the flip-flops 8 in the semiconductor integrated circuit 1. The scan chains sc1 and sc2 are provided with two segments sg1 and sg2, and one segment sg3, respectively.

Suppose that there is a fault f in a combinational circuit 17 of the semiconductor integrated circuit 1, for example. In this case, a specific test pattern is applied to the semiconductor integrated circuit 1 so that an effect D of a fault is captured in registers of the segments sg2 and sg3. The effect D of the fault captured in the segments sg2 and sg3 is shifted therethrough and extracted to the outside while the clock signal 54 is applied to the segments.

Even if there is a fault f in the combinational circuit 17, an effect D of the fault f may not travel to the segments sg2 and sg3 which depends on the type of a test pattern. Therefore, it is determined in step S2 of FIG. 5 whether the test pattern is an effective pattern with which the effect D of the fault f correctly travels, and then a fault detection rate is calculated in step S3.

Explained next is an example in which a fault in the semiconductor integrated circuit 1 of FIG. 1 is detected. Firstly, the scan enable terminal T1 of the semiconductor integrated circuit 1 of FIG.1 is set, for example, to a low level so that the semiconductor integrated circuit 1 enters a capture mode in which parallel input data 9 are captured in the scan registers 8. In this mode, the PRPG circuit 14 in the segment control circuit 5 is set to a hold state.

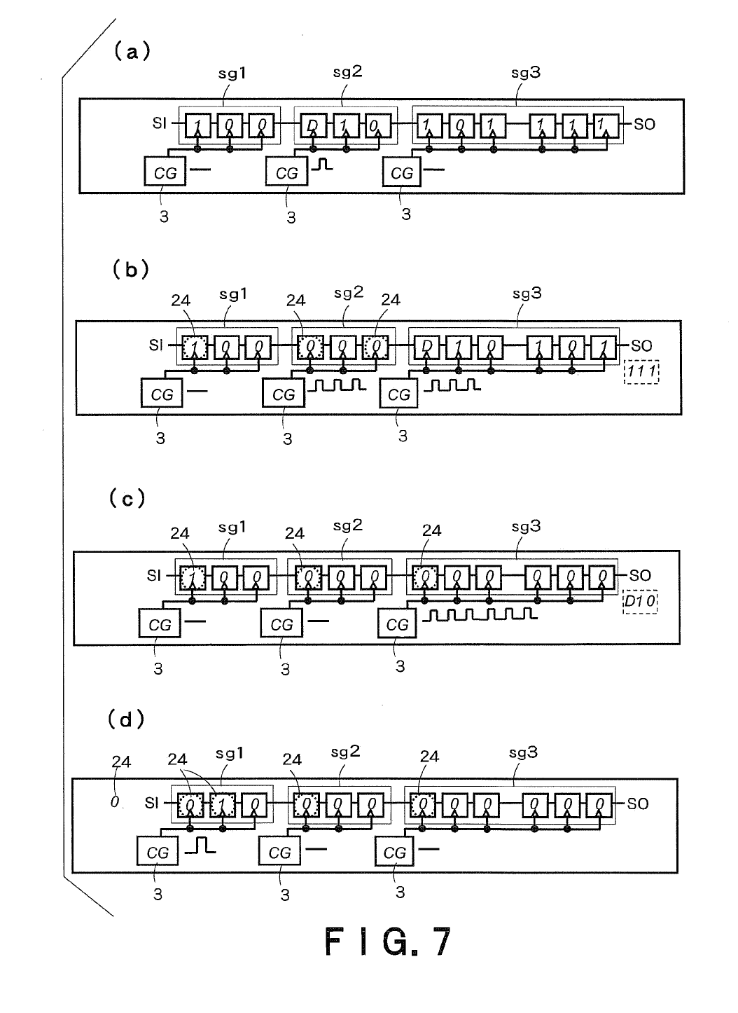

FIG. 7 is a view explaining an operation in which, while an effect D of a fault in the semiconductor integrated circuit 1 is output from a particular segment, care bits used for making the next fault appear are captured in segments. FIG. 7 shows an example in which there are three segments sg1 to sg3 in one scan chain 2. As described above, each segment can perform clock gating and shift operation individually.

Here, an effect D of a fault indicates a fault value that appears by means of care bits in a test pattern.

The design apparatus 7 can identify the node from which an effect D of a fault is output, when a test pattern is generated. The design apparatus 7 controls the segment control circuit 5 so that a particular segment can capture the effect D of the fault. For instance, in an example of FIG. 7(a), the clock signal 54 is applied only to the segment sg2 so that the segment sg2 captures the effect D of the fault. In this case, although data are captured in all scan registers 8 in the segment sg2, only one of the scan registers captures the effect D of the fault, with the data captured in the other scan registers not contributing to the fault detection. The data that do not contribute to the fault detection can be ignored, hence no problem occurs when all scan registers 8 capture the data.

In order to capture the effect D of the fault in the segment sg2, values “010” are set to and held by three registers of the PRPG circuit 14 in the segment control circuit 5. With this setting, the clock gating circuit 3 applies the clock signal 54 only to the segment sg2.

Next, as shown in FIG. 7(b), the scan enable terminal T1 is set to a high level to switch the capture mode to a shift mode to shift data through the scan registers 8. A clock signal 60 is then applied to the PRPG circuit 14 in the segment control circuit 5 so that the PRPG circuit 14 generates pseudo random numbers, with the clock signal 54 applied to the segments sg2 and sg3.

Shown in FIG. 7(b) is an example in which a 3-cycle clock signal 54 is applied to each of the segments sg2 and sg3. With the 3-cycle clock signal 54, the effect D of the fault that exists in the segment sg2 at first is shifted to the segment sg3, while care bits required for making the next fault appear are captured in the segment sg2.

The care bits carry the values indicated by a broken line. These care bits carry the values required for making the next fault appear. The values are required to be output from the segment together with an effect D of a fault. Because, the values are needed for obtaining a fault detection rate.

As shown in FIG. 7(b), in order to apply the clock signal 54 only to the segments sg2 and sg3, the values of three registers of the PRPG circuit 14 in the segment control circuit 5 are shifted by two cycles from “010” described above to “011”. With the values “011”, the PRPG circuit 14 is set in a hold state so that the clock gating circuit 3 applies a 3-cycle clock signal 54 to the segments sg2 and sg3

Next, as shown in FIG. 7(c), six clock signals 54 are applied to the segment sg3 to output (shift out) the effect D of the fault existed in the segment sg3 therefrom. In order to apply the clock signals 54 only to the segment sg3, the values of the three registers of the PRPG circuit 14 in the segment control circuit 5 are shifted by four cycles from “011” described above to “001”. With the values “001”, the PRPG circuit 14 is set in the hold state so that the clock gating circuit 3 applies the six clock signal 54 to the segment sg3.

In this way, the effect D of the fault is output from the scan chain 2 to be acquired for fault determination.

In the state of FIG. 7(c), three care bits are given to the segments, as indicated by a broken line. If there are remaining care bits to be given for making the next fault appear, the remaining care bits are captured, as shown in FIG. 7(d). FIG. 7(d) shows an example of capturing care bits in the segment sg1. The values of three resisters of the PRPG circuit 14 are shifted by two cycles from “001” to “100”. With the values “100”, the PRPG circuit 14 is set in the hold state so that the clock gating circuit 3 applies a 1-cycle clock signal 54 to the segment sg1.

As described above, an effect D of a fault can be output from the scan chain 2 and care bits required for making the next fault appear can be captured in each segment. Therefore, by repeating the operation described above, an effect D of a fault can be output by means of care bits captured in the scan chain 2.

According to the present embodiment, the clock signal 54 is applied only to the segments required for outputting an effect D of a fault and capturing care bits for making the next fault appear. It is therefore achieved in the present embodiment to drive only the segments of minimum necessary for a fault detection process, thus drastically reducing power consumption at the scan test.

### Second Embodiment

In each segment of the scan chain 2, a plurality of scan registers 8 are connected in series. It is referred to as an activation rate to make two or more of scan registers 8 in each segment operate simultaneously. There is a limitation on the activation rate in some cases. If there is a limitation on the activation rate, only a specific number of scan registers 8 within the range of the limitation are allowed to operate.

Explained below in a second embodiment is a fault detection process with a limitation on the activation rate of scan registers 8 in each segment. The difference of the second embodiment from the former embodiment will be mainly explained.

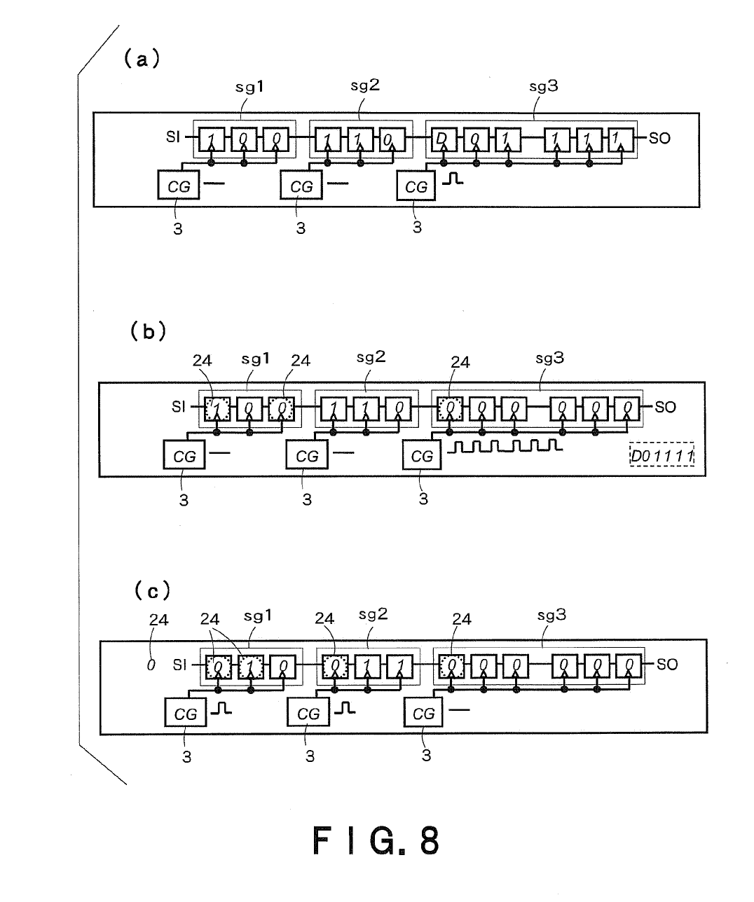

FIG. 8 is a view explaining an operation in which, while an effect D of a fault in the semiconductor integrated circuit 1 is output from a particular segment, care bits used for making the next fault appear are captured in segments. FIG. 8 assumes that the activation rate of scan registers 8 is limited to 50%. There are 12 scan registers 8 in total in the scan chain 2 of FIG. 8. Therefore, six scan registers 8 are operable simultaneously at the activation rate of 50%.

Firstly, as shown in FIG. 8(a), the output of the PRPG circuit 14 in the segment control circuit 5 is held at “001” so that the clock gating circuit 3 applies a 1-cycle clock signal 54 only to the segment sg3 to capture an effect D of a fault in the segment sg3.

Next, as shown in FIG. 8(b), while the PRPG circuit 14 is kept in a hold state, the clock gating circuit 3 applies a 6-cycle clock signal 54 to the segment sg3 to output (shift out) the effect D of the fault from the segment sg3. It is presupposed here that care bits required for making the next fault appear exist at the locations indicated by broken-line circles.

In the case of FIG. 8(b), the scan registers 8 in the segment sg3 are only operating, hence the activation rate is also 50%.

Next, as shown in FIG. 8(c), in order to capture care bits required for making the next fault appear that have not been captured in the segments yet, a 1-cycle clock signal 54 is applied to each of the segments sg1 and sg2. In order to generate this clock signal 54, the values of three registers of the PRPG circuit 14 are shifted by three cycles from “001” to “110”. With the values “110”, the PRPG circuit 14 is set in the hold state so that the clock gating circuit 3 applies a 3-cycle clock signal 54 to the segments sg1 and sg2.

In the case of FIG. 8(c), only the scan registers 8 in the segments sg1 and sg2 operates, hence the activation rate is 50%.

As described above, even if there is a limitation on the activation rate of the scan registers 8, it is possible to operate the segments within a range of the limitation, thereby further restricting power consumption and detecting fault accurately.

### Third Embodiment

As explained in the first and second embodiments, fault detection requires the extraction of an effect D of a fault that appears with a test pattern from a segment and the capture of care bits that make the next fault appear. In this case, it is preferable to extract an effect D of a fault from a segment with as few numbers of clocks as possible.

Accordingly, a third embodiment described below has a feature in that segments are realigned first and then an effect D of a fault is transferred through the segments at as few number of clocks as possible. The alignment is performed by the testability realizer 71 in the design apparatus 7.

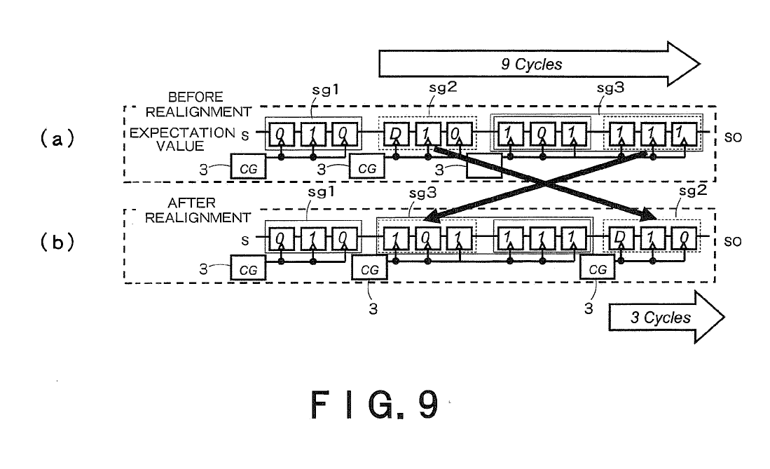

FIG. 9 is a view of an example in which the order of segments aligned in a scan chain 2 is changed. FIG. 9(a) shows the scan chain 2 before the change in the order of alignment of segments. FIG. 9(b) shows the scan chain 2 after the change in the order of alignment of segments. In the case of FIG. 9(a), the scan chain 2 must receive a 9-cycle clock signal 54 until an effect D of a fault that exists in the segment sg2 is output from the output terminal SO. By contrast, in the case of FIG. 9(b), the scan chain 2 requires only a 3-cycle clock signal 54 until an effect D of a fault is output from the output terminal SO because of the replacement of the segment having the effect D of the fault with the last segment. In this way, it is achieved that the number of input clock signals 54 is drastically reduced with reduction of power consumption.

In FIG. 9, the realignment of segments in the scan chain 2 is conducted so as to make easy the transfer of an effect D of a fault. Not only the segments, but also it is preferable to provide the latch circuit 12 of the clock gating circuit 3 in FIG. 2 that consumes a large power in a shift operation at the last-stage side of the scan chain 2.

The realignment process at the testability realizer 71 is preferably performed before step S1 of the flow chart in FIG. 5. That is, the process of realigning the segments in the scan chain 2 is first conducted, and then the test-pattern generating process may be conducted. By this process sequence, it is possible to generate a test pattern capable of transferring an effect D of a fault with as few numbers of clocks as possible.

Accordingly, in the third embodiment, the process of realigning the segments in the scan chain 2 is first conducted, and then the test pattern is generated, under consideration of an effect D of a fault and power consumption in a shift operation. Therefore, it is possible to reduce the number of clocks until the extraction of an effect D of a fault to the outside and to reduce power consumption in the third embodiment.

### Fourth Embodiment

In the first to third embodiments, described above, the PRPG circuit 14 is provided in the segment control circuit 5, for clock gating of each segment in the scan registers 8. However, the PRPG circuit 14 may be omitted. A fourth embodiment which will be described later has a feature in that the PRPG circuit 14 is omitted from the segment control circuit 5.

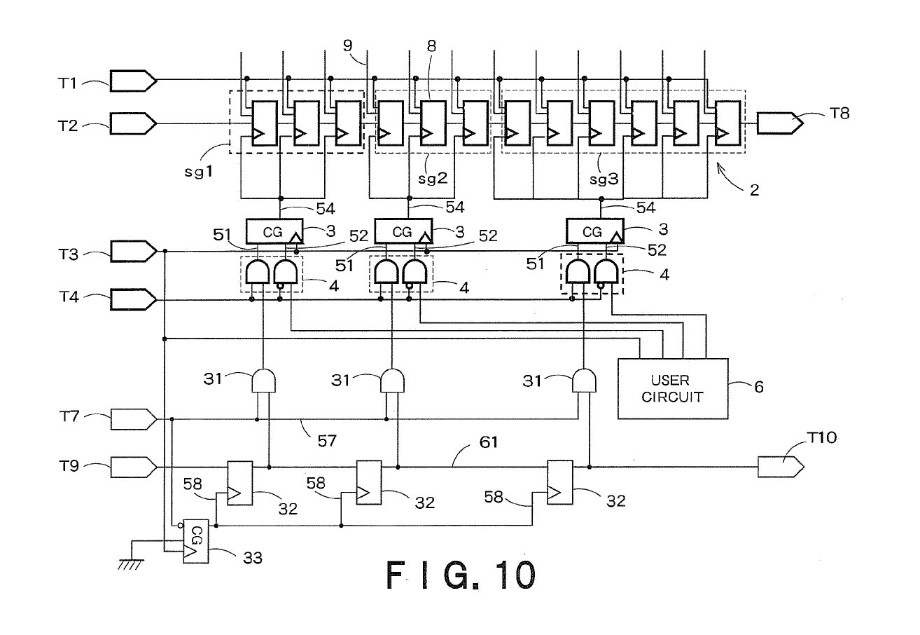

FIG. 10 is a circuit diagram schematically showing the configuration of a semiconductor integrated circuit 1 according to the fourth embodiment. In FIG. 10, the circuit elements common to FIG. 1 are given the same reference numerals or signs. The differences between FIGS. 1 and 10 will be mainly explained hereinbelow.

The semiconductor integrated circuit 1 of FIG. 10 has an AND circuit 31, a flip-flop 32, and a clock gating circuit 33 for each segment and clock gating circuit 3, instead of the PRPG circuit 14 The AND circuit 31 generates a logical product of a hold signal 57 and a shifted input signal 61. There is no such a shifted input signal 61 in FIG. 1 to be input to a shifted-input terminal T9. The shifted input signal 61 to be input to the shifted-input terminal T9 is a signal of a bit pattern obtained by shifting a signal in the PRPG circuit 14 by a specific number of cycles. That is, in the semiconductor integrated circuit 1 of FIG. 10, pseudo random numbers generated by the design apparatus 7 are input via the shifted-input terminal T9, as the shifted input signal 61. The shifted input signal 61 is shifted by each flip-flop 32 and input to the corresponding AND circuit 31. Each flip-flop 32 performs a shift operation in synchronism with a clock signal 58 from the clock gating circuit 33.

In this way, there is no need to provide the PRPG circuit 14 in the semiconductor integrated circuit 1 of FIG. 10, thus simplifying the internal configuration of the semiconductor integrated circuit 1. With the semiconductor integrated circuit 1 of FIG. 10, the same operation as that of FIG. 7 can be conducted. Hereinbelow, a test fault detection process in the semiconductor integrated circuit 1 of FIG. 10 will be explained with reference to FIG. 7.

Firstly, in FIG. 7(a), an effect D of a fault is captured in the segment sg2. In order to perform the capture, a shifted input signal 61 composed of three bits “010” is applied to the AND circuits 31, together with a high-level hold signal 57 via a hold terminal T7 for one cycle. Accordingly, the clock gating circuits 3 apply a 1-cycle clock signal 54 only to the segment sg2 to capture an effect D of a fault in the segment sg2.

Next, in FIG. 7(b), a 3-cycle clock signal 54 is applied to both of the segments sg2 and sg3 for a shift operation to an effect D of a fault. In order to perform the shift operation, a shifted input signal 61 composed of three bits “011” is applied to the AND circuits 31, together with a high-level hold signal 57 via the hold terminal T7 for three cycles. Accordingly, the clock gating circuits 3 apply a 3-cycle clock signal 54 only to the segments sg2 and sg3 to shift the effect D of the fault from the segment sg2 to sg3.

Next, in FIG. 7(c), a 6-cycle clock signal 54 is applied to the segment sg3 to shift the effect D of the fault to the outside. In order to perform the shift operation, a shifted input signal 61 composed of three bits “001” is applied to the AND circuits 31, together with a high-level hold signal 57 via the hold terminal T7 for six cycles. Accordingly, the clock gating circuits 3 apply a 6-cycle clock signal 54 only to the segment sg3 to shift the effect D of the fault from the segment sg3 to the outside.

Next, in FIG. 7(d), a 1-cycle clock signal 54 is applied to the segment sg1 to give care bits for making the next fault appear. In order to give the care bits, a shifted input signal 61 composed of three bits “100” is applied to the AND circuits 31, together with a high-level hold signal 57 via the hold terminal T7 for one cycle. Accordingly, the clock gating circuits 3 apply a 1-cycle clock signal 54 only to the segment sg1 to give the car bits thereto.

As described above, according to the fourth embodiment, the gating control signal 51 for clock control of the segments sg1 to sg3 is generated by means of the shifted input signal 61 applied from the outside of the semiconductor integrated circuit 1. Therefore, there is no need to provide the PRPG circuit 14 for generating the gating control signal 51 in the semiconductor integrated circuit 1, hence the internal configuration of the semiconductor integrated circuit 1 is simplified, in the fourth embodiment.

Moreover, in the case of generating the gating control signal 51 by the PRPG circuit 14 provided in the semiconductor integrated circuit 1, there is a variation in the generation time of the gating control signal 51. This is because of the change in the number of shift operations in the PRPG circuit 14 up to the generation of the gating control signal 51. On the contrary, the present embodiment employs the shifted input signal 61 generated outside the semiconductor integrated circuit 1, hence the gating control signal 51 can be generated quickly for a constant time period in the semiconductor integrated circuit 1.

### Fifth Embodiment

In a fifth embodiment which will be explained below, a PRPG circuit 14 for scan compression provided in the semiconductor integrated circuit 1 is used for generating a gating control signal 51.

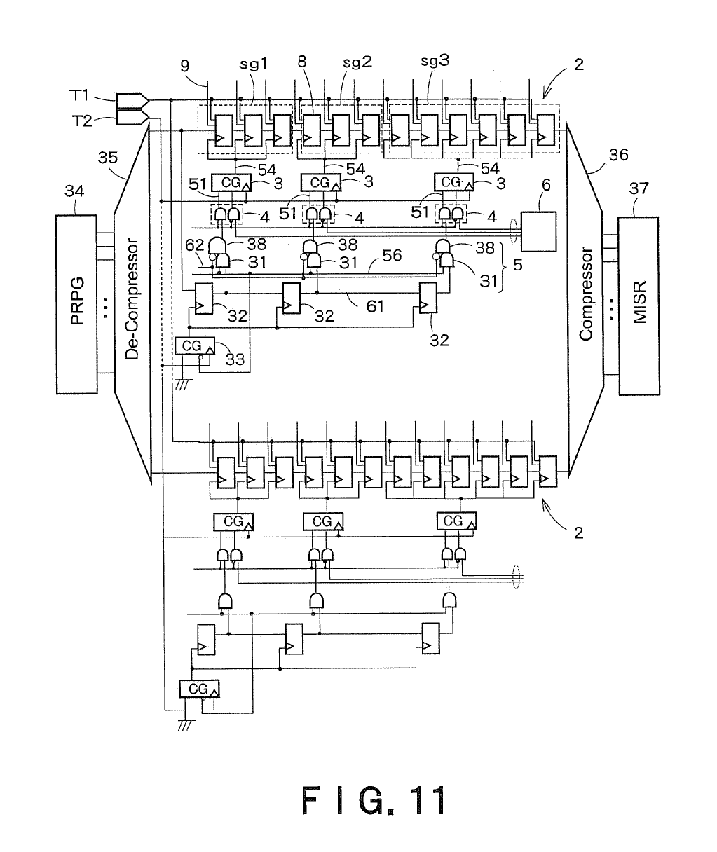

FIG. 11 is a circuit diagram schematically showing the configuration of a semiconductor integrated circuit 1 according to a fifth embodiment. In FIG. 11, the circuit elements common to FIG. 1 are given the same reference numerals or signs. The differences between FIGS. 1 and 11 will be mainly explained hereinbelow.

A semiconductor integrated circuit 1 of FIG. 11 has a PRPG circuit 34 and a de-compressor 35 at the scan input side and a compressor (a first compressor) 36 and a MISR (a second compressor) 37 at the scan output side. Provided between the de-compressor 35 and the compressor 36 are scan chains 2 of a plurality of series-connected scan registers 8. Shown in FIG. 11 is an example in which two scan chains 2 are provided in parallel between the de-compressor 35 and the compressor 36. However, there is no particular limitation on the number of scan chains 2 provided between the de-compressor 35 and the compressor 36.

A pseudo random-number pattern generated by the PRPG circuit 34 is converted by the de-compressor 35 into control signals and a clock signal 53 for controlling the scan chains 2. The PRPG circuit 34 generates pseudo random numbers having a specific cycle based on a specific generator polynomial with a seed value supplied from the design apparatus 7 as an initial value. Therefore, the design apparatus 7 applies a desired seed value to the PRPG circuit 34 with a presupposition on the operation timing of the control signals and the clock signal 53. Then, the de-compressor 35 outputs the control signals and the clock signal 53 at the timing presupposed by the design apparatus 7.

The present embodiment has a feature in that a signal (a shifted input signal 61, hereinafter) necessary for the segment control circuit 5 to generate a gating control signal 51 is generated by the PRPG circuit 34 for use in scan compression. In other words, in the present embodiment, there is no need to provide a dedicated PRPG circuit 34 such as shown in FIG. 3 in the segment control circuit 5. That is, the PRPG circuit 34 for use in scan compression is used for generation of a shifted input signal 61 described above, which is then input to the segment control circuit 5.

The fifth embodiment is the same as FIG. 10 on the point that the shifted input signal 61 is input to the semiconductor integrated circuit 1 from outside. The internal configuration of the segment control circuit 5 of FIG. 11 is similar to that of the segment control circuit 5 of FIG. 10.

Hereinbelow, the differences between the segment control circuit 5 of FIG. 11 and the counterpart of FIG. 10 will be mainly explained. In the present embodiment, the PRPG circuit for use in scan compression also generates a shifted input signal 61 for generation of a gating control signal, as described above. In order to achieve this, the design apparatus 7 presupposes the operation timing of the gating control signal 51 when a seed value is applied to the PRPG circuit 34 and adjusts the seed value in accordance with the presupposed operation timing so that the de-compressor 35 can output a desired shifted input signal 61.

Although the segment control circuit 5 of FIG. 11 is similar to that of FIG. 10, another AND circuit 38 is connected to each AND circuit 31. The AND circuit 38 is provided for keeping, with a signal 62, each segment of the scan chain 2 in the hold state until a shift operation is completed using a gating control signal generated by the PRPG circuit 34. With the semiconductor integrated circuit 1 of FIG. 11, the operation similar to that of FIG. 7 can be conducted.

As described above, according to the fifth embodiment, the PRPG circuit for use in scan compression is used for generating a shifted input signal 61 for generation of a gating control signal. Therefore, there is no need to provide the PRPG circuit 14 in the segment control circuit 5, hence the fifth embodiment achieves a simplified internal structure for the segment control circuit 5.

At least part of the design apparatus explained in the embodiments may be configured with hardware or software. When it is configured with software, a program that performs at least part of the functions of the design apparatus may be stored in a storage medium such as a flexible disk and CD-ROM, and then installed in a computer to run thereon. The storage medium may not be limited to a detachable one such as a magnetic disk and an optical disk but may be a standalone type such as a hard disk drive and a memory.

Moreover, a program that achieves the function of at least part of the design apparatus may be distributed via a communication network (including wireless communication) such as the Internet. The program may also be distributed via an online network such as the Internet or a wireless network, or stored in a storage medium and distributed under the condition that the program is encrypted, modulated or compressed.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor integrated circuit having one or more of scan chains each having series-connected flip-flops that exist in an internal circuit, each scan chain being divided into a plurality of segments, each segment being controllable a timing of a clock signal,
the semiconductor integrated circuit comprising:
a clock gating circuit capable of being shared by the scan chains and configured to generate a plurality of clock signals for driving each segment, the clock gating circuit being provided for each scan chain; and
a segment control signal generator configured to generate a control signal to be used when the clock gating circuit generates the clock signals so that an effect of a fault of the internal circuit is transferred through one of the segments and care bits corresponding to a next fault are captured in a corresponding segment,
wherein, based on the control signal, the clock gating circuit applies the clock signal to one of the segments so that the effect of the fault of the internal circuit is transferred through the one segment, applies the clock signal to a particular segment so that care bits for making a fault appear are captured in the particular segment, and stops the clock signal to a segment that does not have no relation with capture of the care bits and extraction of the fault.

2. The semiconductor integrated circuit of claim 1, the segment control signal generator generates the control signal based on a hold signal and a seed input signal.

3. The semiconductor integrated circuit of claim 2, wherein the segment control signal generator includes a pseudo random number generator configured to generate the same pseudo random numbers repeatedly for a specific cycle, and arbitrarily adjusts a timing of the clock signals generated by the clock gating circuit, based on the hold signal and the seed input signal.

4. The semiconductor integrated circuit of claim 3, wherein the seed input signal varies in accordance with the pseudo random numbers generated by the pseudo random number generator repeatedly for the specific cycle, and
the segment control signal generator generates the control signal by a logical operation using the seed input signal and the hold signal.

5. The semiconductor integrated circuit of claim 1 further comprising a control-signal selection circuit configured to select either the control signal generated by the segment control signal generator or a user-specified signal to be used in a normal operation of the semiconductor integrated circuit and to apply the selected signal to the clock gating circuit.

6. The semiconductor integrated circuit of claim 1 further comprising:
a pseudo random number generator configured to generate pseudo random numbers corresponding to input signals to be input to the scan chains, the clock gating circuit, and the segment control signal generator, respectively;
a de-compressor configured to convert the pseudo random numbers into the input signals;
a first compressor configured to compress the number of output signals of the scan chains; and
a second compressor configured to further compress the number of the signals compressed by the first compressor,
wherein the pseudo random number generator generates pseudo random numbers related to the control signal generated by the segment control signal generator.

7. The semiconductor integrated circuit of claim 6, wherein the pseudo random number generator generates a control input signal for controlling the segment control signal generator based on a shift input signal applied from a design apparatus so that the clock signals are generated at a timing presupposed by the design apparatus.

8. A design apparatus for designing a semiconductor integrated circuit having one or more of scan chains each having series-connected flip-flops that exist in an internal circuit, a clock gating circuit provided to be shared by the scan chains and configured to generate a clock signal for driving the flip-flops, each scan chain being divided into a plurality of segments capable of being separately driven, the design apparatus comprising:
a test pattern generator configured to generate a test pattern that carries care bits required for making appear a fault at each of all nodes in the semiconductor integrated circuit;
a seed input signal generator configured to generate a seed input signal and apply the seed input signal to the semiconductor integrated circuit, the seed input signal being used for controlling a timing at which the clock gating circuit generates the clock signal so that an effect of a fault in the semiconductor integrated circuit travels through any of the segments and the care bits are captured in a corresponding segment; and
a pattern inspector configured to acquire an effect of a fault output from the scan chains to inspect the test pattern.

9. The design apparatus of claim 8, wherein the seed input signal generator generates the seed input signal so that the number of segments that are driven simultaneously in each scan chain does not exceed an activation rate that is a rate of segments that can be driven simultaneously.

10. The design apparatus of claim 8 further comprising a testability realizer configured to adjust the order of connection of the segments to give a least sum of the number of clock signals to be input to a particular segment until the effect of the fault is output from the particular segment and the number of clock signals to be input to another particular segment until the care bits are set in the latter particular segment,
wherein the test pattern generator generates the test pattern to be applied to the segments for which the order of connection has been adjusted by the testability realizer.

11. The design apparatus of claim 8, wherein the seed input signal generator generates the seed input signal so that the clock gating circuit applies the clock signal to one of the segments in order to transfer the effect of the fault of the internal circuit through the one segment and applies the clock signal to a particular segment in order to capture care bits for making a fault appear in the particular segment, and stops the clock signal to a segment that has no relation with capture of the care bits and extraction of the fault.

12. The design apparatus of claim 8, wherein the semiconductor integrated circuit includes:
a pseudo random number generator configured to generate pseudo random numbers corresponding to input signals to be input to the scan chains and the clock gating circuit, respectively;
a de-compressor configured to convert the pseudo random numbers into the input signal;
a first compressor configured to compress the number of output signals of the scan chains; and
a second compressor configured to further compress the number of the signals compressed by the first compressor,
wherein the seed input signal generator generates the seed input signal so that the pseudo random number generator generates pseudo random numbers.

13. The design apparatus of claim 8, wherein the semiconductor integrated circuit includes:
a segment control signal generator configured to generate a control signal to be used by the clock gating circuit when the clock signals are generated so that an effect of a fault of the internal circuit is transferred through one of the segments and care bits corresponding to a fault next to the fault are captured in the corresponding segment,
wherein the seed input signal generator generates the seed input signal that can arbitrarily adjust a timing of the clock signals generated by the clock gating circuit.

14. The design apparatus of claim 13, wherein the seed input signal varies in accordance with the pseudo random numbers generated repeatedly for a specific cycle by the pseudo random number generator,
wherein the segment control signal generator generates the control signal by a logical operation with the seed input signal and the hold signal.

15. A design method for designing a semiconductor integrated circuit having one or more of scan chains each having series-connected flip-flops that exist in an internal circuit, a clock gating circuit capable of being shared by the scan chains and configured to generate a clock signal for driving the flip-flops, each scan chain being divided into a plurality of segments that can be separately driven, comprising:
generating a test pattern that carries care bits required for making appear a fault at each of all nodes in the semiconductor integrated circuit;
generating a seed input signal and applying the seed input signal to the semiconductor integrated circuit, the seed input signal being used for controlling a timing at which the clock gating circuit generates the clock signal so that an effect of a fault in the semiconductor integrated circuit travels through any of the segments and the care bits are captured in a corresponding segment; and
acquiring an effect of a fault output from the scan chains to inspect the test pattern.

16. The design method of claim 15, wherein the seed input signal is generated so that the number of segments that are driven simultaneously in each scan chain does not exceed an activation rate that is a rate of segments that can be driven simultaneously.

17. The design method of claim 15 further comprising:
adjusting the order of connection of the segments to give a least sum of the number of clock signals to be input to a particular segment until the effect of the fault is output from the particular segment and the number of clock signals to be input to another particular segment until the care bits are captured in the latter particular segment,
wherein the test pattern is generated to be applied to the segments for which the order of connection has been adjusted.

18. The design method of claim 15, wherein the seed input signal is generated so that the clock gating circuit applies the clock signal to one of the segments based on the control signal in order to transfer the effect of the fault of the internal circuit through the one segment, applies the clock signal to a particular segment in order to capture care bits for making a fault appear in the particular segment, and stops the clock signal to a segment that has no relation with capture of the care bits and extraction of the fault.

19. The design method of claim 15, wherein the semiconductor integrated circuit includes:
a pseudo random number generator configured to generate pseudo random numbers corresponding to input signals to be input to the scan chains, the clock gating circuit, and the segment control signal generator, respectively;
a de-compressor configured to convert the pseudo random numbers into the input signal;
a first compressor configured to compress the number of output signals of the scan chains; and
a second compressor configured to further compress the number of the signals compressed by the first compressor,
wherein the seed input signal is generated so that the pseudo random number generator generates pseudo random numbers.

20. The design method of claim 15, wherein the semiconductor integrated circuit includes:
a segment control signal generator configured to generate a control signal to be used by the clock gating circuit when generating the clock signals so that an effect of a fault of the internal circuit is transferred through one of the segments and care bits corresponding to a fault next to the fault are captured in the corresponding segment,
wherein the seed input signal is capable of arbitrarily adjusting a timing of the clock signals generated by the clock gating circuit.
